(19) United States
(12) Patent Application Publication
(10) Pub. No.: US 2003/0027444 A1
(43) Pub. Date: Feb. 6, 2003

(54) Method of establishing an electrical connection

(75) Inventor: Gerhard Engeser, Schramberg-Waldmossingen (DE)

Correspondence Address: BIERMAN MUSERLIAN AND LUCAS, 600 THIRD AVENUE, NEW YORK, NY, 10016

(73) Assignee: EIV Engeser Innovative Verbindungstechnik GmbH

(21) Appl. No.: 10/190,498

(22) Filed: Jul. 8, 2002

Related U.S. Application Data
(62) Division of application No. 09/923,183, filed on Aug. 6, 2001.

(51) Int. Cl. H05K 1/00; H01R 12/00; B23P 19/00

(52) U.S. Cl. 439/83; 29/860; 29/742; 29/747

(57) ABSTRACT

A method is provided for establishing an electrical connection between at least one connecting piece of a workpiece and at least one wire. Firstly the end of the at least one wire is prepared. Then the prepared end of the at least one wire is positioned on the terminal or connecting piece of the workpiece. Thereafter the at least one connecting piece and the prepared end of the at least one wire are welded together by laser radiation.

The invention relates to a method of establishing an electrical connection between at least one connecting piece of a workpiece and at least one conductor or wire, to an apparatus for carrying out the method and to a contact piece for attachment to the end of the wire.

Such methods are for example used to connect conductors, wires or lines to switches, for instance miniature snap switches. The method is to be suitable for automation and monitoring, and is to be efficient and economical as well as reliable in processing. A requirement of the connection of the wire to the switch is that it is of high quality and ensures a reliable electrical contact between the wire and switch.

Conventional methods of establishing electrical connections between conductors, wires and terminal pieces or connection pieces of workpieces are based on soldering or resistance welding.

In the soldering method the end of the wire is soldered to the connecting piece of the switch. With small switches and large production numbers the solder connection is not favourable because this type of connection can be monitored and automated only at great expenditure. Implementation of very large production numbers is therefore possible only with high personnel numbers and it is extremely difficult to ensure uniform quality of the connection. Possible causes for defects in quality are for example solder accumutations and solder splashing which can lead to a short-circuit or cold faulty soldered joints which are not recognised or not recognised completely. In addition, during soldering the maximum permissible heating time of the switch terminals may be exceeded and this may lead to damaging the switching system and thus failure of the switch. Incorrectly soldered cable ends may also lead to the switch being unusable. It is hardly possible-to correct wrongly soldered cable ends because the renewed heating of the connecting piece usually results in damage to the switches. Further factors which can lead to damage of the switch are irregular stranded-wire positioning on the connecting piece so that the required distance from the live parts and the switch outer edge is partially not achieved (may lead to short-circuiting or leaks) and the damaging of the outer contour of the switch by the soldering iron.

With resistance welding, once again with large production numbers the personnel intensity required is high. Admittedly, using travel/measuring systems or power-driven welding heads the weld quality may be monitored far better than the quality of a soldered joint, but it is not possible to exclude hidden errors, for example by solder splashing due to the heating, embrittling of the conductor stranded wires at the exit from the insulation (leading to a danger or breakage under load), or bending of the terminals during the welding. With resistance welding, incorrectly welded-on wires, as with soldering, cannot be subsequently reestablished.

An objective of the present invention is thus an improved methold of establishing an electrical connection between at least one terminal or connecting piece of a workpiece and at least one wire.

A further objective of the present invention is to provide a contact piece which is particularly suitable for carrying out the method.

A further objective of the present invention is to provide an apparatus for carrying out the method.

These objectives are achieved by the teachings in claims 1, 11 and 17.

Further developments of these teachings are set forth in the subsidiary claims.

An advantage of the method according to claim 1 is that the laser welding can be carried out completely automatically.

As a result, the entire method can be carried out completely automatically.

A further advantage of the method according to claim 1 is that the welding of the contact piece to the terminal or connecting piece takes place without contact and without the aid of additional substances. Furthermore, in laser welding only very short laser pulses are necessary. Consequently, the heat stress of the workpiece is very low and the occurrence of metal or solder splashing can be avoided.

The position of the contact pieces on the connecting or terminal pieces can be monitored completely automatically before the laser welding. If the workpiece has several connecting pieces to which a respective wire is to be connected, the correct assignment of the wires to the terminals or connecting pieces can be monitored completely automatically before they are welded. This therefore makes it possible to correct errors in the arrangement of the wires relatively to the connecting pieces before the final connection.

The contact pieces may for example be connected to the wire ends by squeezing. Furthermore, the contact pieces may be shaped so that the positioning at the terminal or connecting pieces is effected by placing them on the latter. For this purpose in particular connecting pieces according to claim 11 can be employed.

If two or three connecting pieces are arranged in alignment on the workpiece it is possible with the contact pieces according to claim 11 to angle the sleeve-like portions of the contact pieces so that all the wires can extend adjacent each other parallel to the alignment line of the connecting pieces.

By choice of the axial length of the sleeve-like portion a uniform distance of the wires from the workpiece or switch can be assured.

The cross-section of the sleeve opening can be adapted to the shape of the connecting pieces.

Finally, it is possible to carry out the method fully automatically in the apparatus according to the invention.

Further properties and advantages of the method according to the invention, the contact piece according to the invention and the apparatus according to the invention will become clear from the following description of concrete examples of embodiment made with reference to the drawings.

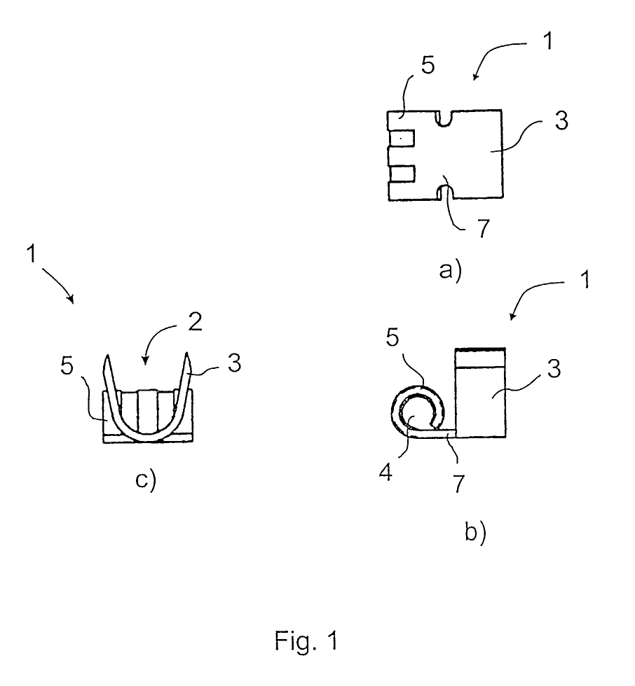

FIGS. 1a-1c show a first embodiment of the contact piece according to the invention before attachment to the wire.

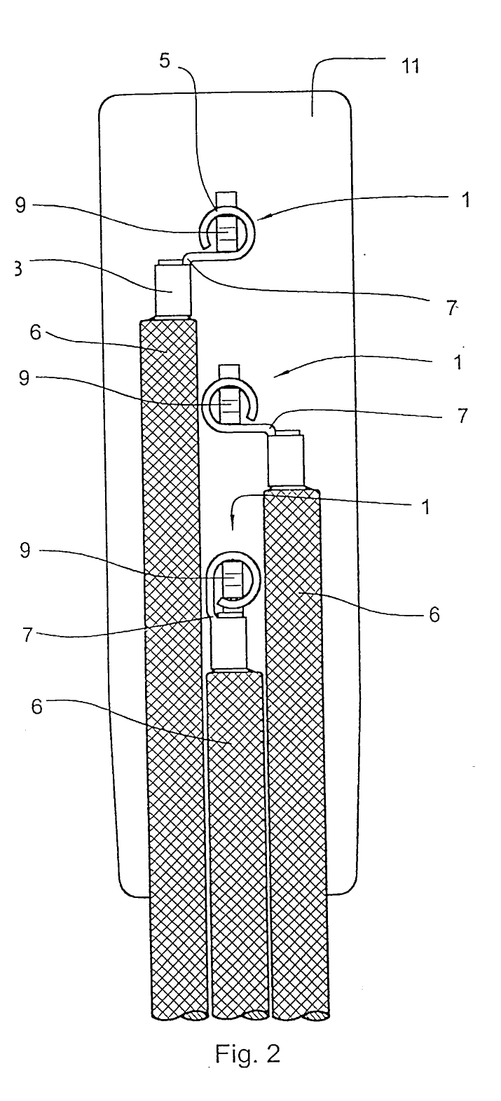

FIG. 2 is a plan view of a switch having three terminal or connecting pieces on which three wires are positioned by means of the contact pieces according to the invention.

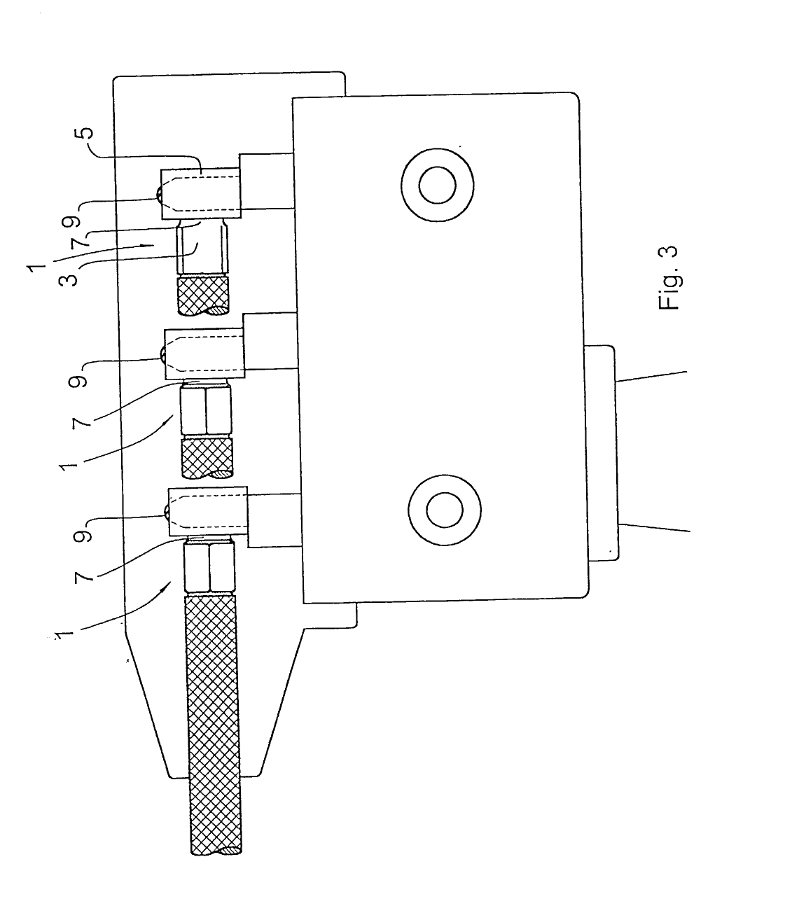

FIG. 3 is a side elevation of the switch of FIG. 2.

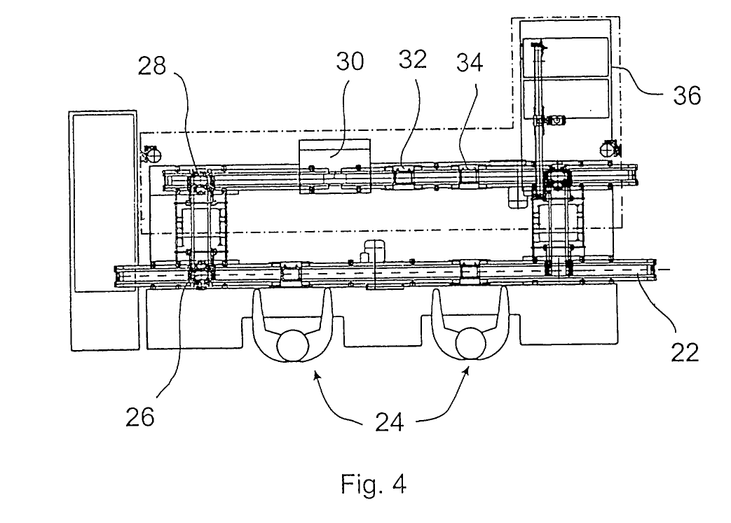

FIG. 4 is a plan view of an apparatus for carrying out the method according to the invention.

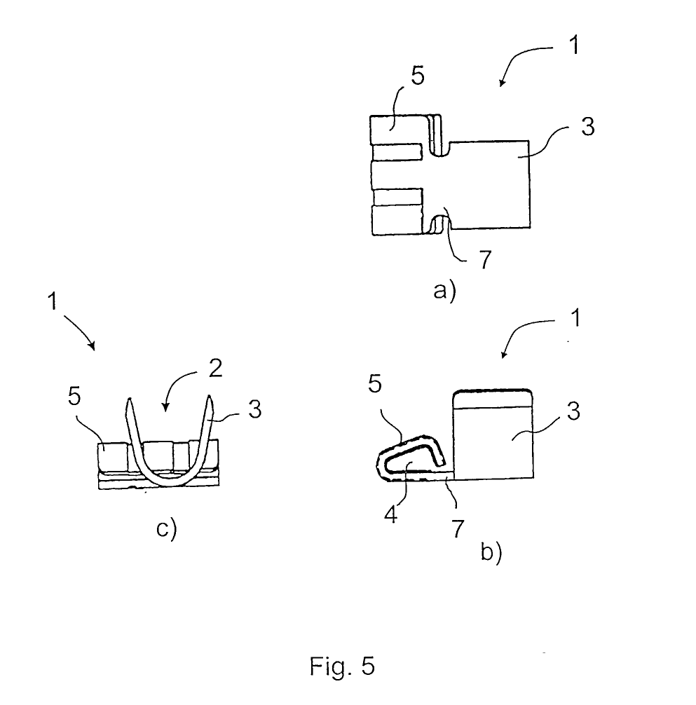

FIG. 5 shows a second example of embodiment of the contact piece according to the invention.

First, in FIGS. 1a-1c an embodiment of the contact piece according to the invention is illustrated, as it is employed in the method according to the invention. The contact piece 1 consists of a first portion 3, a second portion 5 and a material bridge 7 joining the two portions together.

The first portion 3 has a U-shaped form and serves to receive a wire end. After insertion of the wire end into the U-shaped receiving section 2 of the first portion 3 the legs of the U-shaped receiving section 2 are bent over to establish a crimp connection to the wire end.

The second portion 5 is rolled up to form a sleeve-like eye, the centre axis of which extends perpendicularly to the direction of the wires inserted into the first portion 3. The axial length of the eye of the second portion 5 is greater than the width of the connecting web 7. It is possible to bend the second portion 5 relatively to the first portion 3 through up to 900 oppositely to the opening direction of the U-shape first portion 3 (see FIG. 2).

The second portion 5 serves for plugging the contact piece 1 onto a connecting piece 9 of a workpiece 11 as illustrated in FIGS. 2 and 3.

Ideally, the dimensions of the sleeve-like second portion 5 are chosen so that the cross-sectional area of the sleeve opening 4 is just large enough to accommodate the connecting piece 9 in order to avoid accidental sliding of the contact piece 1 off the connecting piece 9. In addition, the axial length of the second portion 5 is chosen so that the connecting piece 9 is almost completely surrounded by the sleeve-like eye (see FIG. 3)

In particular brass, copper and copper beryllium alloys are suitable as materials for the contact piece 1.

The workpiece 11 illustrated in FIGS. 2 and 3 represents a miniature snap switch having three terminal or connecting pieces 9. The three connecting pieces 9 of the miniature snap switch 11 are in alignment along a line. It is frequently desirable to lead the wires 6-away in the direction of the alignment line of the connecting pieces 9. With the contact piece 1 according to the invention this can be done by providing the middle wire with a contact piece 1, the second portion of which is not bent with respect to the first portion 3. The two outer wires 6 are in contrast provided with contact pieces 1 having a second portion 5 bent in each case through 900 with respect to the first portion 3 on attachment to the wires. In this manner the two wires can be led laterally past the connecting pieces 9 and the middle wire.

FIG. 4 shows an embodiment of the apparatus for carrying out the method according to the invention. The apparatus 20 comprises a transport system 22 for workpieces with which the latter are conveyed to the individual stations. The—stations include two component insertion stations 24 (shown in FIG. 4 as manual working stations), a station-for insertion monitoring 26, a laser welding station 28, a potting or encapsulation station 30, a station for production control 32, a station for data marking and reject destruction 34 and a component withdrawal station 36 with good/poor product deposits. In addition, a control unit (not illustrated) is present for fully automatic control. This unit also performs the fully automatic control of the component insertion when the insertion is not to be carried out manually.

In the insertion stations 24 the cables 6 provided with contact pieces 1 are arranged at the terminal or connecting pieces 9 of the switch 11. The sleeve-like second portions 6 of the contact pieces 1 are plugged onto the connecting pieces 9 of the switch 11 so that for example in the case of a miniature snap switch equipped with three connecting pieces the configuration of FIG. 2 or FIG. 3 is achieved. The insertion stations operate completely automatically but if required can also be configured as manual locations.

Providing the ends of cable 6 with contact pieces 1 is carried out fully automatically in a preparation station (not illustrated). This station is connected directly to the component insertion stations 24 when the apparatus operates completely automatically. In the preparation station the ends of the wires 6 are each inserted into the respective U-shaped receiving section 2 of the first portion 3 of a contact piece 1. The legs of the first portion 3 are then bent over to compress the portion 3 with the deinsulated wire end. Since the pressing operation can easily be controlled by monitoring the crimp force this operation can readily be automated. On connection of the wire 6 to the contact piece 1 the second portion 5 of the contact piece 1 is possibly simultaneously bent over as well.

The workpiece is then transported by the transport system 22 to the insertion monitoring station 26. There the sleeves are again pressed onto the connecting pieces by means of a test stamp. In addition, using an image recognition system it is monitored whether all the wires are plugged on and the respective connecting pieces 9 properly assigned. This is done by the different colouring of the wires 6. The image recognition system can also check the proper position of the wires 6. If the insertion monitoring station 26 detects an error it can be-corrected before further conveying of the workpiece to the laser welding station 28.

After the insertion monitoring the workpiece is conveyed to the laser welding station 28 where the contact pieces 1 and the connecting pieces 9 are fused together using a laser beam.

From the laser welding station the workpieces are then conveyed to the potting or encapsulation station 30 where they are potted. In the following station, the production control 32, using an image recognition system the potted workpiece is monitored and the contacting of the switches and switch actuation are checked.

Thereafter, in the station for data marking and reject destruction 34, a data designation of the workpieces is conducted using a hot embossing stamp. Parts which have been detected as defective in the production control 32 are destroyed in the reject destruction. This is done for example by severing the wires directly behind the workpiece.

Thereafter the workpieces are transported to the component withdrawal where they are separated into satisfactory and reject components and discharged.

In addition the apparatus includes control devices for example for controlling the laser and/or the transport system.

Using a laser makes a contactless welding possible between the contact pieces 1 and the connecting pieces 9. Furthermore, it is not necessary to use additive substances. The extremely short irradiation of the contact piece 1 and connecting piece 9 keeps the heat stress of the switch low. In addition, up to the laser welding the connection between the contact piece 1 and connecting piece 9 is still detachable, i.e. incorrectly inserted components or parts can be corrected before the welding without any loss of quality. This leads to a reduction in the material consumption. Furthermore, by controlling the plugging depth of the contact pieces on the connecting pieces uniform quality can be assured.

Although a manual working station has been described for the component insertion, the latter can also be carried out using a fully automatic cable making machine. By monitoring the pressing force the crimping of the contact pieces to the cable end can be monitored in simple manner.

Although an angling of the second portion with respect to the first portion of 900 has been described, the second portion may be angled in infinitely variable manner with respect to the first portion. The degree of the angling can be adapted to the diameter of the wire.

FIG. 5 shows a second embodiment of the contact member 1 according to the invention. In contrast to the first embodiment the second portion 5 bent in sleeve-like manner does not have a circular base area but a polygonal one. In addition, the axial length of the sleeve is greater than in the first example of embodiment.

By differently configuring the sleeve-like second portion 5 the contact piece 1 can be adapted to different connecting pieces 9.

What I claim is:

1. A method of establishing an electrical connection between at least one connecting piece (9) of a workpiece (11) and at least one wire (6) comprising:
preparing the end of the at least one wire (6);
positioning the prepared end of the wire (6) on the connecting piece (9); and
welding the prepared end to the connecting piece (6) by laser radiation.

2. The method of claim 1 wherein the preparation of the end of the at least one wire (6) comprises attaching thereto a contact piece (1).

3. The method of claim 2 wherein the contact piece (1) is pressed onto the wire end.

4. The method of claim 2 wherein the contact piece (1) is plugged onto the connecting piece (9) for the positioning.

5. The method of claim 1 wherein the dimensions of the contact piece (1) are chosen so that the contact piece (1) is prevented from sliding off the connecting piece (9).

6. The method of claim 1 wherein, prior to the laser welding, the positioning of the prepared end of the wire (6) on the connecting piece (9) is monitored.

7. The method of claim 1 wherein each workpiece (11) has at least two connecting pieces (9) and one wire (6) is connected to each connecting piece (9) through a contact piece (1) at the end of wire (6).

8. The method of claim 7 wherein the connection of the at least two wires (6) to the at least two connecting pieces (9) is performed simultaneously.

9. The method of claim 7 wherein the wires (6) are arranged parallel to the line of alignment of the at least two connecting pieces (9) and at least one of the contact pieces (1) is bent so that the wires (6) extend parallel adjacent each other after the positioning of the contact pieces (1) on the connecting pieces (9).

10. The method of claim 7 wherein, prior to laser welding, the assignment of the wires (6) to the connecting pieces (9) is monitored.

11. The method of claim 2 including the additional step of encapsulating the workpiece (11) after the laser welding.

12. The method of claim 2 wherein all the steps are performed by computer-control in a fully automatic manner.

13. A contact piece comprising a first portion (3) for establishing a connection to a wire (6) and a second portion (5) shaped so that said second portion (5) can be placed onto a connecting piece (9), wherein the first portion (3) is connected to the second portion (5) via a flexible web (7) so that the second portion (5) can be bent perpendicularly to its center axis out of the line of alignment with the wire (6).

14. The contact piece of claim 13 wherein it is adapted to be connected to the wire (6) via a crimp connection.

15. The contact piece of claim 13 wherein the second portion (5) is bent in a sleeve-like manner so that it can be plugged onto a connecting piece (9).

16. The contact piece of claim 15 wherein the sleeve opening of the second portion (5) has a round cross-section.

17. The contact piece of claim 15 wherein the sleeve opening of the second portion (5) has a polygonal cross-section.

18. The contact piece of claim 13 wherein the center axis of the sleeve-like second portion (5) is perpendicular to the alignment of an end of a wire (6) inserted into the first portion.

19. The contact piece of claim 15 wherein the dimensions of the sleeve-like portion (5) are adapted to the connecting piece (9) of a workpiece (11).

20. The contact piece of claim 13 wherein the contact piece (19) is bent out of a planar basic form.

21. The contact piece of claim 13 wherein the contact piece (1) consists of a member of the group consisting of brass, copper and copper-beryllium alloy.

22. An apparatus for carrying out the method of claim 1, comprising:
a component inserting station (24) for positioning prepared wires t6) on the connecting pieces (9) of workpieces (11), a laser welding station (28) for welding the ends of the prepared wires (6) to connecting pieces (9), and a transport system (22) for conveying the workpieces (11).

23. An apparatus of claim 22 wherein the component inserting station (24) is preceded by a preparation station for preparing the wires (6) by attaching contact pieces (1).

24. An apparatus 22 wherein a potting station (30) is additionally provided for potting the workpieces (11) after the laser welding.

25. An apparatus of claim 22 wherein between the component inserting station (24) and the laser welding station (28), a station for component insertion monitoring (26) is also provided and/or following the potting station (30), a station for production control (32) is provided.

26. An apparatus of claim 22 comprising a component withdrawal station (36).

27. An apparatus of claim 22 comprising a control means for fully automatic control of the apparatus.
